(19) United States
(12) Patent Application Publication
(10) Pub. No.: US 2024/0140783 A1
(43) Pub. Date: May 2, 2024

(54) METHOD FOR MANUFACTURING A DEVICE COMPRISING TWO SEMICONDUCTOR DICE AND A DEVICE THEREOF

(71) Applicant: STMICROELECTRONICS S.r.l., Agrate Brianza (IT)

(72) Inventors: Mark Andrew SHAW, Milano (IT); Lorenzo CORSO, Ruginello (IT); Matteo GARAVAGLIA, Magenta (IT); Giorgio ALLEGATO, Monza (IT)

(73) Assignee: STMICROELECTRONICS S.r.l., Agrate Brianza (IT)

(21) Appl. No.: 18/489,729

(22) Filed: Oct. 18, 2023

(30) Foreign Application Priority Data
Oct. 31, 2022 (IT) 102022000022395

(51) Int. Cl. B81B 7/00; B81C 1/00

(52) U.S. Cl. CPC B81B 7/0074; B81C 1/0023; B81B 2207/012; B81C 2203/0792

(57) ABSTRACT

A device and method for manufacturing a device comprising two semiconductor dice. The device is formed by a first die and a second die. The first die is of semiconductor material and integrates electronic components. The second die has a main surface, forms patterned structures, and is bonded to the first die. Internal electrical coupling structures electrically couple the main surface of the first die to the second die. External connection regions extend on the main surface of the first die. A package packages the first die, the second die and the internal electrical coupling structures and partially surrounds the external connection regions, the external connection regions partially protruding from the package.

### BACKGROUND

### Technical Field

Embodiments of the present disclosure relate to a method for manufacturing a device comprising two semiconductor dice and to a device so obtained. Furthermore, embodiments of the disclosure relate to a Chip Scale Package (CSP) device that includes a Micro-Electro-Mechanical-System (MEMS) die, for example, a MEMS sensor, and a semiconductor die integrating electronic components, such as an Application Specific Integrated Circuit (ASIC).

### Description of the Related Art

As known, dice integrating a MEMS device are protected on one side (generally the top side) by a cap, often made by another die. Furthermore, they are normally associated with dice containing electronic circuits for controlling and/or preprocessing signals and data supplied by the MEMS device, such as an ASIC, so as to form a MEMS device. In the following, therefore, reference will be made to a system formed by a MEMS die and the ASIC thereof, without losing generality.

In a MEMS device described herein, the MEMS die and the cap thereof are stacked with the ASIC-integrating die and are carried by an organic substrate with Land Grid Array (LGA) external coupling.

For example, the stacked arrangement allows for reducing the area of the system and allows its use in both portable and wearable electronic apparatuses and systems.

The desire to use more MEMS devices in electronic systems and apparatuses having small dimensions (e.g., in smart watches, earphones, etc.) entails a request for smaller dimensions of MEMS devices with regard to the area and thickness of the MEMS devices.

For example, the document IT 10 2013 902 204 294 (corresponding to U.S. Pat. No. 9,327,964) describes a method for manufacturing a die assembly which uses the die integrating the ASIC as a cap of the MEMS die, thus saving a die.

Other patents (for example U.S. Pat. No. 9,527,727) teach other solutions teaching stacking a MEMS die on a cap and on an ASIC die, using through vias.

However, the use of through vias is expensive and these solutions do not allow integration of all parts of the system in a same package, such as in a CSP device.

### BRIEF SUMMARY

A process for manufacturing a microelectromechanical device may be summarized as including: bonding a first wafer of semiconductor to a second wafer, the first wafer integrating electronic components; thinning the first wafer; bonding the first wafer to a third wafer, the third wafer including patterned structures; thinning the third wafer; removing the second wafer to obtain a composite wafer having a main surface formed by the first wafer; electrically coupling the first wafer and the third wafer through internal electrical coupling structures; forming external connection regions on the main surface; and forming a package packaging the first wafer, the third wafer and the internal electrical coupling structures and partially surrounding the external connection regions the external connection regions protruding partially from the package.

The first wafer may be an ASIC wafer and the third wafer may be a MEMS wafer. The second wafer may be of semiconductor or glass. The second wafer may be of glass and removing the second wafer includes detaching the second wafer through laser light application. The process may further include, before bonding the first wafer to the second wafer, forming first and second recesses in the second wafer and forming contact regions on the main surface of the first wafer, and bonding the first wafer to the second wafer includes forming a bonding layer having first bonding layer openings at the first and second recesses and arranging the first and second recesses of the second wafer and the first bonding layer openings at the contact regions of the first wafer; removing the second wafer includes thinning the second wafer up to reaching the first and second recesses, forming through recesses; and forming external connection regions includes forming bumps in the first bonding layer openings.

The process may further include, before bonding the first wafer to the second wafer, forming third recesses in the second wafer; and bonding the first wafer to the second wafer further includes forming second bonding layer openings at the third recesses; after the step of removing the second wafer, removing a portion of the body below the third recesses, forming through openings in the body; and electrically coupling the first wafer and the third wafer includes forming coupling wires extending between contact regions on the main surface of the first wafer and contact regions extending on the third wafer below the through openings.

The external connection regions may be bumps and may form an LGA interface. The internal electrical coupling structures may be bonding wires extending between external contact pads formed on the main surface of the first wafer and further contact pads formed on the third wafer.

The process may further include forming cavities in the first wafer before bonding the first wafer to the third wafer. The third wafer may include third contact pads facing the first wafer, the process further including, after the step of removing the second wafer, selectively removing a portion of the body above the third contact pads, wherein electrically coupling the first wafer and the third wafer includes forming coupling wires passing through the removed portion of the body.

The process may include singulating the composite wafer before or after the steps of electrically coupling the first and the third wafers, forming external connection regions and forming a package.

A device may be summarized as including: a first die of semiconductor integrating electronic components; a second die of semiconductor bonded to the first die and forming patterned structures, the first die having a main surface; internal electrical coupling structures electrically coupling the main surface of the first die to the second die; external connection regions on the main surface of the first die; and a package packaging the first die, the second die, and the internal electrical coupling structures and partially surrounding the external connection regions, the external connection regions protruding partially from the package.

The package may cover and may be in contact with the main surface of the first die. The device may also include a bonding layer superimposed on the main surface of the first die, such that the package covers and is in contact with the bonding layer. The bonding layer may have through openings and the external connection regions may traverse the through openings.

### BRIEF DESCRIPTION OF THE SEVERAL VIEWS OF THE DRAWINGS

Further understanding of the present disclosure will emerge with the aid of the following embodiments now described with reference to the attached drawings.

FIGS. 1-9 show cross-sections of an embodiment of a semiconductor wafer in subsequent manufacturing steps.

FIG. 10 shows a cross-sectional view of a portion of the wafer of FIG. 9 after a dicing step.

FIG. 11 shows a top perspective view of the wafer portion of FIG. 10.

FIG. 12 shows a cross-sectional view similar to FIG. 10, in a subsequent manufacturing step.

FIG. 13 shows a top perspective view, similar to FIG. 11, of the wafer portion of FIG. 12.

FIG. 14 shows a cross-sectional view of a device obtained by encapsulating the portion of FIG. 12.

FIG. 15A shows a top perspective view of the device of FIG. 14, in ghost view.

FIG. 15B shows a top perspective view of the device of FIG. 14.

FIG. 16 shows a cross-sectional view of an alternative embodiment of the process of FIGS. 1-15B, in a subsequent step to FIG. 9.

FIG. 17 shows a cross-sectional view of a device obtained after dicing the wafer of FIG. 16.

FIGS. 18-27 show cross-sectional views of an alternative embodiment of a semiconductor wafer in subsequent manufacturing steps.

FIG. 28 shows a cross-sectional view of a portion of the wafer of FIG. 27 after a dicing step.

FIG. 29 shows a top perspective view of the wafer portion of FIG. 28.

FIG. 30 shows a cross-sectional view similar to FIG. 28, in a subsequent manufacturing step.

FIG. 31 shows a top perspective view, similar to FIG. 29, of the wafer portion of FIG. 30.

FIG. 32 shows a cross-sectional view of a device obtained by packaging the portion of FIGS. 30 and 31.

### DETAILED DESCRIPTION

The following description refers to the arrangement shown; consequently, expressions such as “above”, “below”, “top”, “bottom”, “right”, “left” refer to the attached Figures and are not to be interpreted in a limiting manner.

The process for manufacturing a MEMS device described herein uses three wafers, i.e., a MEMS wafer, an ASIC wafer and a carrier wafer, which is eliminated so as to have a reduced final thickness.

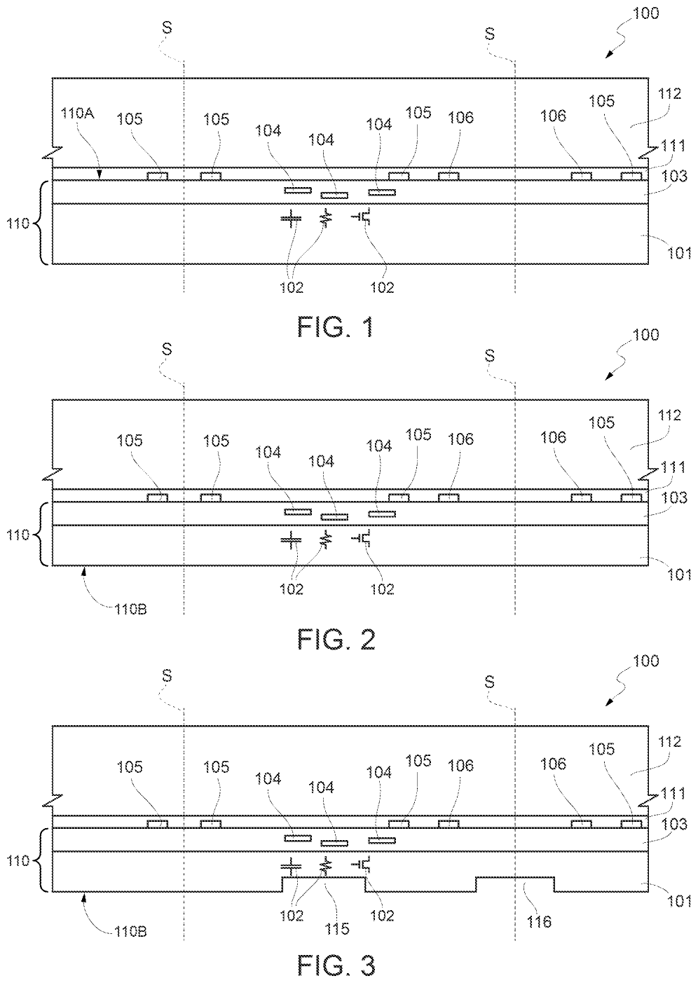

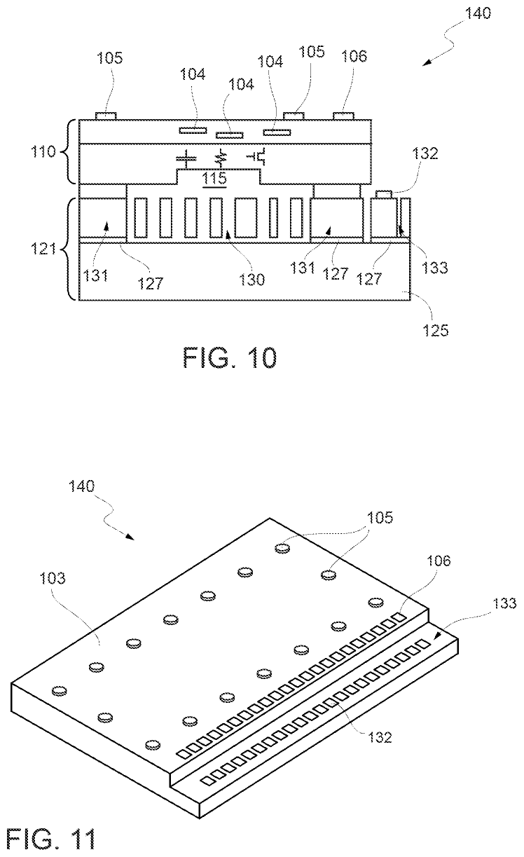

FIGS. 1-9 show subsequent steps for manufacturing a composite wafer 100 which is subsequently diced along scribe central lines S, shown in dashed lines, intended to separate different dice 140 (See FIG. 10), as explained in detail below.

In FIGS. 1-9, the portion arranged between two scribe central lines S of the composite wafer 100 (central portion in FIGS. 1-9) is intended, after dicing and packaging, to form a single device (MEMS device) and the portions to the left and right of the single device represent portions of further devices. In the example shown, the left and right portions of the central portion are arranged symmetrically with respect to the respective adjacent scribe central lines S.

FIG. 1 shows the composite wafer 100 obtained after known initial processing steps and including: forming, in a body 101 of semiconductor material such as silicon, electronic components 102, and forming an electronic circuit; forming a passivation layer 103 above the body 101, including forming electrical contact regions and connections, of conductive material, for example of metal such as aluminum, towards the electronic components 102 (metallizations 104) and towards contact regions, including first and second contact pads 105, 106. The metallizations 104 may form a connection structure known as Redistribution Layer (RDL). The body 101 and the passivation layer 103 collectively form an ASIC wafer 110. The passivation layer 103 forms a main surface (hereinafter referred to as the front surface 110A of the ASIC wafer 110). The first and second contact pads 105, 106 have the purpose of electrically connecting the electronic components 102 to each other and towards the outside and are arranged above the passivation layer 103 or are recessed with respect thereto, so as not to protrude therefrom, in a manner known to the person skilled in the art. The first and second contact pads 105, 106 are of conductive material, such as copper. As clarified below, in the embodiment shown, the first contact pads 105 are intended for allowing outward connection through bumps, the second contact pads 106 are intended for allowing internal connection through wires;
forming a carrier wafer bonding layer 111 on the front surface 110A of the ASIC wafer 110. For example, the carrier wafer bonding layer 111 is a metal or a metal alloy such as AuSn; alternatively, it may be of CuSn or AlGe AuSn, AuGe, AuSi, AlSi; and
bonding a carrier wafer 112 to the ASIC wafer 110, using the carrier wafer bonding layer 111. For example, the carrier wafer 112 may be of semiconductor material such as silicon or glass. Bonding is carried out at high temperatures, such as over 200° C., and constitutes a temporary bonding.

In FIG. 2, the body 101 is thinned and polished from the back, until it reaches a small thickness, for example 100-120 μm. Thus, another main face is formed, hereinafter referred to as a rear surface 110B of the ASIC wafer 110.

In FIG. 3, a first cavity 115 and a second cavity 116 are formed in the body 101 from the rear surface 110B. In some embodiments, a photolithographic process is used, including definition of a resist mask and silicon etching; then the masking resist is removed. As explained in detail below, the first cavity 115 is intended to be arranged above the movable structures of the MEMS wafer (to be bonded) and the second cavity 116 is intended to be arranged above contact pads of the MEMS wafer.

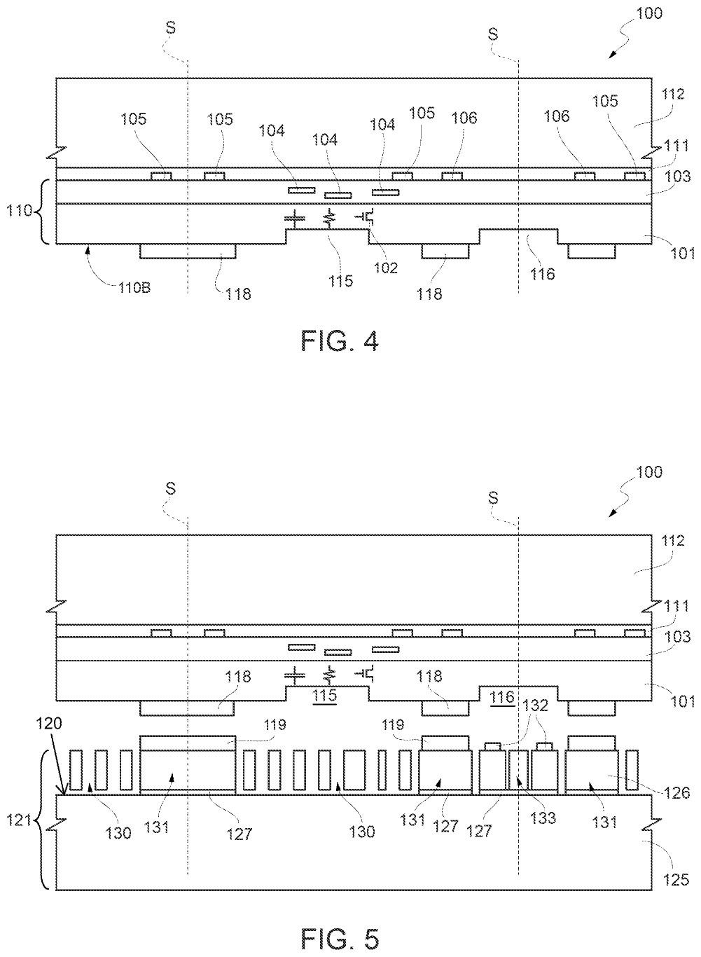

In FIG. 4, first bonding regions 118 are formed on the rear surface 110B of the ASIC wafer 110. For example, the first bonding regions 118 may be of AuSn, selectively deposited on the sides of the cavities 115, 116.

In the process illustrated, similar bonding regions (second bonding regions 119) are formed on a front surface 120 of a MEMS wafer 121, as shown in FIG. 5. The second bonding regions 119 may also be of AuSn.

The MEMS wafer 121 here comprises a first semiconductor layer 125 and a second semiconductor layer 126, for example both of silicon. The first and the second semiconductor layers 125, 126 are mutually superimposed and integral through dielectric regions 127. The dielectric regions 127 electrically insulate the first and the second semiconductor layers 125, 126, where provided, but may be interrupted for forming semiconductor or metal electrical connections, in a known manner.

The first semiconductor layer 125, for example a substrate or a substrate and an epitaxial layer, generally does not accommodate electrical structures, except for possible electrical connections, not shown for purposes of clarity.

The second semiconductor layer 126 forms sensitive regions or suspended actuation regions. To this end, the second semiconductor layer 126 has through openings which delimit suspended structures 130 in FIGS. 5-14. As obvious to the person skilled in the art, the suspended structures 130 are supported by suspension structures, which may be both of the elastic type (springs) and of the rigid type (along one or more directions) and extend between the suspended structures 130 and anchoring regions 131. The anchoring regions 131 are generally formed by the same second semiconductor layer 126 and integral with the first semiconductor layer 125 through the dielectric regions 127.

In a known manner, the suspension structures (not shown) allow the movement of the suspended structures 130 according to one or more degrees of freedom, based on the desired function.

The second bonding regions 119 are generally formed on the anchoring regions 131 or in any case on other fixed portions of the second semiconductor layer 126.

Third contact pads 132 extend on other fixed portions 133 of the MEMS wafer 121, also formed in the second semiconductor layer 126 and fixed to the first semiconductor layer 125 through the dielectric regions 127.

In FIG. 5, the body 101 is bonded to the MEMS wafer 121 through the first and the second bonding regions 118, 119 which are here mutually aligned. Bonding occurs at a temperature such as to allow adhesion and bonding between the first and the second bonding regions 118, 119, for example, at 270° C.

As is noted in FIG. 5, the geometry is designed and the bonding of the ASIC wafer 101 to the MEMS wafer 121 is performed so that the first cavity 115 faces the suspended structures 130 (to allow the movement thereof without limitations) and the second cavity 116 faces the third contact pads 132 (to allow the electrical connection thereof, as described below).

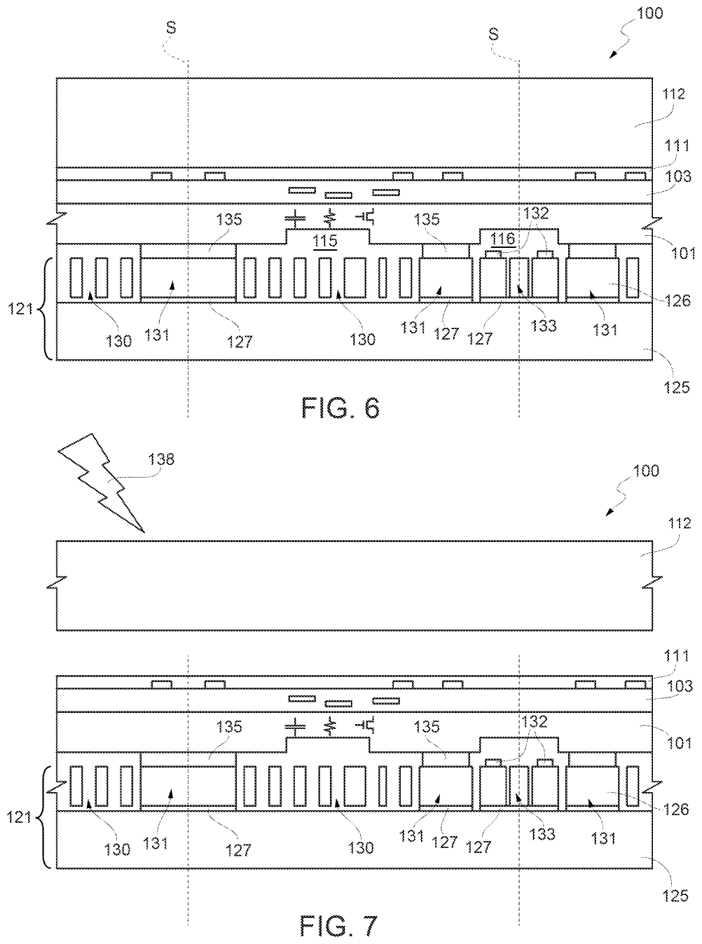

After bonding (FIG. 6), the first and the second bonding regions 118, 119 are joined to form common bonding regions 135.

The composite wafer 100 is then thinned from the back, so as to reduce the thickness of the first semiconductor layer 125 down to a small value, for example, 100-120 μm.

In FIG. 7, the carrier wafer 112 is removed. For example, in case of a carrier wafer 112 of glass, a laser light 138 may be used. Alternatively, the detachment may be obtained thermally. In this manner, the composite wafer 100 (apart from the residues of the carrier wafer bonding layer 111) is reduced to a very small thickness, for example, 0.25 mm.

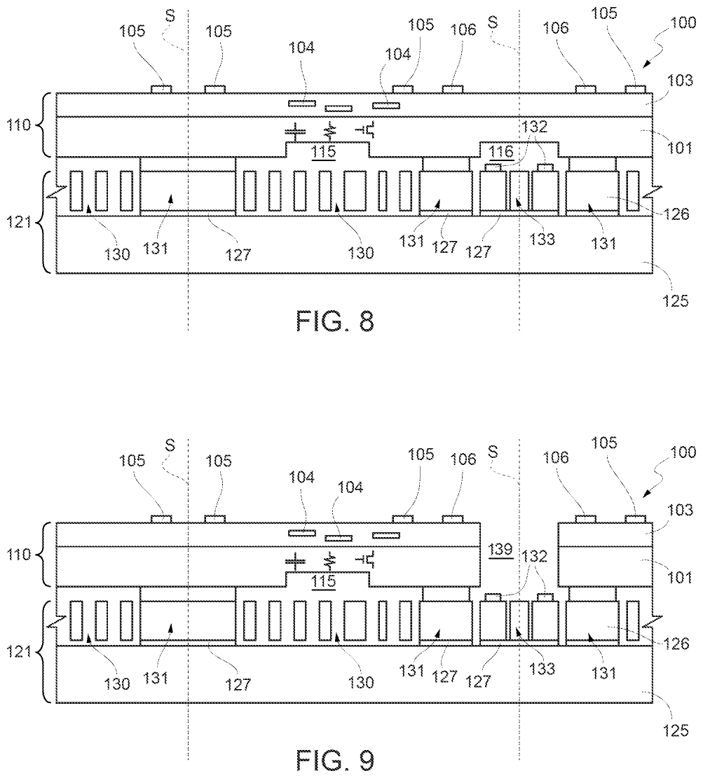

Subsequently, FIG. 8, the residues of the carrier wafer bonding layer 111 are completely removed, using a suitable solvent, such as a long chain apolar organic solvent.

As a result, the first and the second contact pads 105, 106 become accessible on the front of the composite wafer 100.

In FIG. 9, the portions of the body 101 and of the passivation layer 103 above the second cavity 116 are removed. For example, the body 101 and the passivation layer 103 may be diced by a dicing saw or such portions may be removed by masked etchings. A through opening 139 (incorporating the second cavity 116), which makes the third contact pads 132 accessible from the outside, is therefore formed in the ASIC wafer 110.

The composite wafer 100 of FIG. 9 is then singulated along the scribe central lines S. The dicing may occur using dicing saw or by laser dicing, in a per se known manner, thereby obtaining a composite die 140, as shown in FIG. 10. Hereinbelow, for ease of understanding, the portions of the wafers and layers of the composite wafer 100 forming the composite die 140 and obtained from the singulation operation are indicated with the same reference numbers used for the composite wafer 100.

FIG. 11 is a top perspective view of the composite die 140 of FIG. 10, showing the first and second contact pads 105, 106 and the third contact pads 132, placed on different levels.

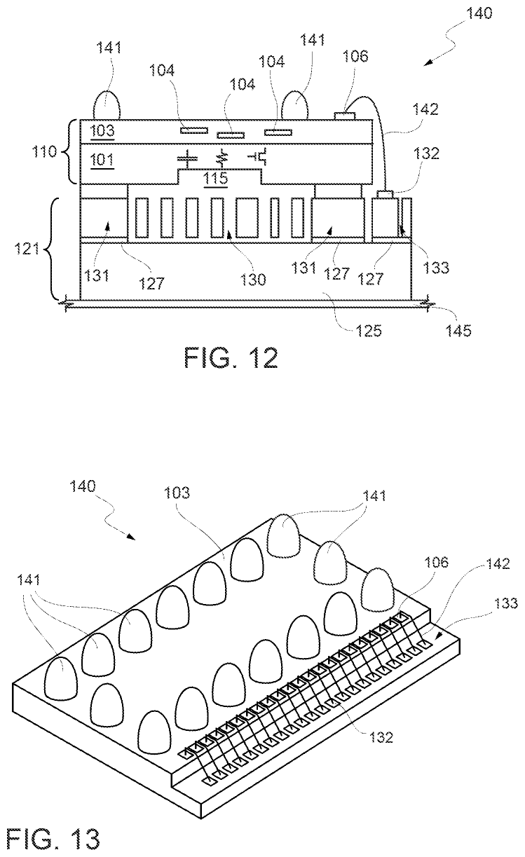

In FIG. 12, the composite die 140 is fixed to a tape 145, generally adhesive, having other composite dice 140 fixed thereto (in a manner not shown), at a mutual distance.

Then, bumps 141 are formed on the first contact pads 105. For example, the bumps 141 may be made by “drop” of balls of an alloy, such as an alloy of Sn, Ag, Cu (SAC alloy), subsequently remelted, or other suitable material. Other techniques for forming bumps, known to the person ordinarily skilled in the art, are also usable.

According to an alternative embodiment, the bumps 141 may be formed before dicing the composite wafer 100, at wafer level.

Furthermore, before or after singulation, bonding wires 142 are formed and electrically couple the second contact pads 106 to the third contact pads 132 (“wirebonding”).

FIG. 13 shows in top perspective view the composite die 140 thus obtained.

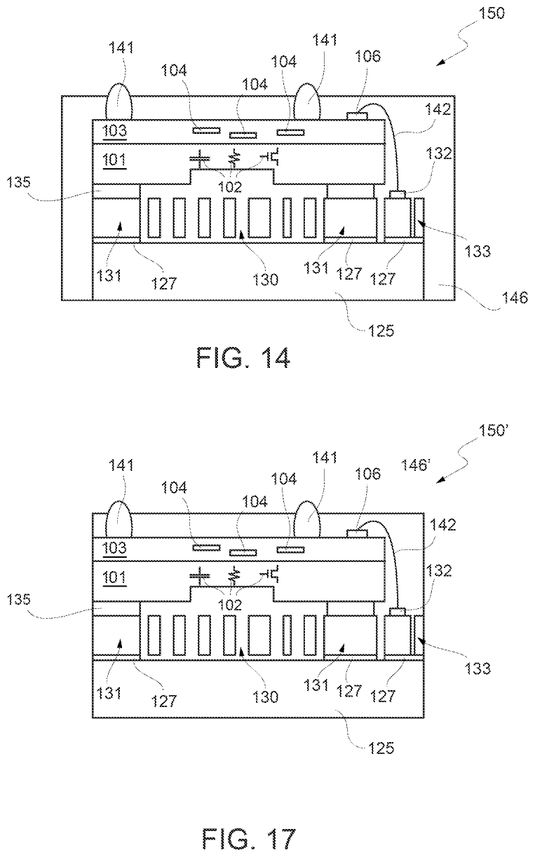

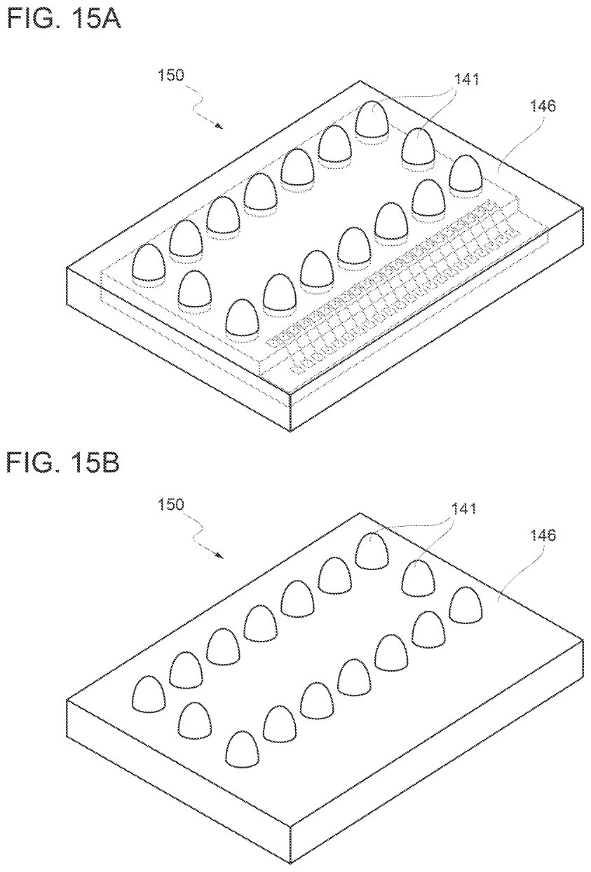

In FIG. 14, the composite die 140 (together with the adjacent dice arranged on the same tape 145) is packaged in a sealing mass 146, for example, of resin. The structure thus obtained is subsequently singulated, resulting in packaged devices 150, each forming a MEMS device, as visible in FIGS. 15A, 15B showing the packaged devices in ghost and, respectively, in an external perspective view.

In the packaged device 150 of FIG. 14, the sealing mass 146 completely covers the passivation layer 103 and the sides of the composite die 140 and laterally surrounds the bottom part of the bumps 141. The sealing mass 146 also fits into the through opening 139 and completely incorporates the wire bondings 142. The end of the bumps 141 therefore protrudes from the sealing mass 146 and allows the electrical connection of the packaged device 150, in a per se known manner.

In this manner, the packaged devices 150 are protected by the sealing mass 146 both upwardly and laterally and are contactable from the top side.

Thanks to the thickness reduction of the ASIC wafer 110 and of the MEMS wafer 121, to the formation of the cap by the ASIC wafer 110 and to the removal of the carrier wafer 112, the packaged device 150 may have an extremely reduced thickness. For example, the packaged device 150 may have an overall height of 360 μm, with a height of the assembly MEMS region 121 and ASIC region 110 of 250 μm, a thickness of the sealing mass 146 above the ASIC region 110 of 110 μm and a bump 141 protruding by 70 μm from the sealing mass 146.

The assembly formed by MEMS region 121 and ASIC region 110 forms a single chip, with the MEMS part and the ASIC part mechanically and functionally integral. The packaged device 150 is therefore operationally reliable.

The packaged device 150 may be formed using manufacturing steps common to this type of devices and not complex, without using through vias, therefore at low costs and with good control. The final device therefore has comparatively low costs.

Owing to the possibility of forming one or more through openings 139 in different peripheral positions, the third contact pads 132 may be arranged on different sides of the ASIC region 110 or even in any position of the surface, in case of masked etchings of the through openings 139, providing the designer with a wide degree of layout freedom.

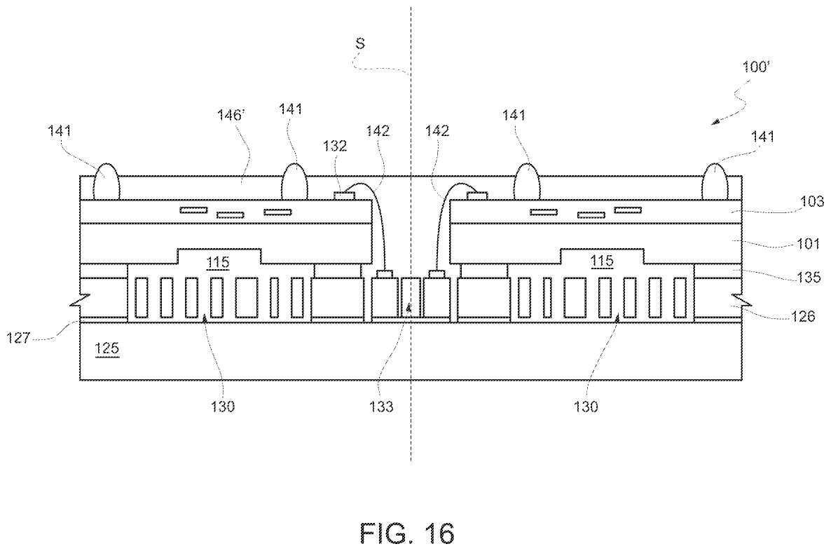

FIG. 16 shows an embodiment where the composite wafer 100 is not singulated after the removal of the carrier wafer 112 (FIG. 7), the removal of the residues of the carrier wafer bonding layer 111 (FIG. 8), and the formation of the through opening 139 in the ASIC wafer 110 (FIG. 9), but is packaged at the wafer level.

As shown in FIG. 16, the composite wafer 100 of FIG. 9 is processed to form the bumps 141 and the bonding wires 142. Subsequently, a sealing mass 146′ is printed on the composite wafer (here indicated by 100′) and covers the top part thereof.

Subsequently, FIG. 17, the composite wafer 100′ is singulated, to form a plurality of packaged devices 150′.

In FIG. 17, the sealing mass 146′ covers the top part of the device 150′ and only part of its sides (zone of the ASIC region 110 and of the bonding wires 142).

In practice, with the package at the chip level, shown in FIGS. 10-14, a more complete protection is obtained by the sealing mass 146, while with the package at the wafer level, shown in FIGS. 16-17, the number of singulation operations and therefore the manufacturing cost are reduced.

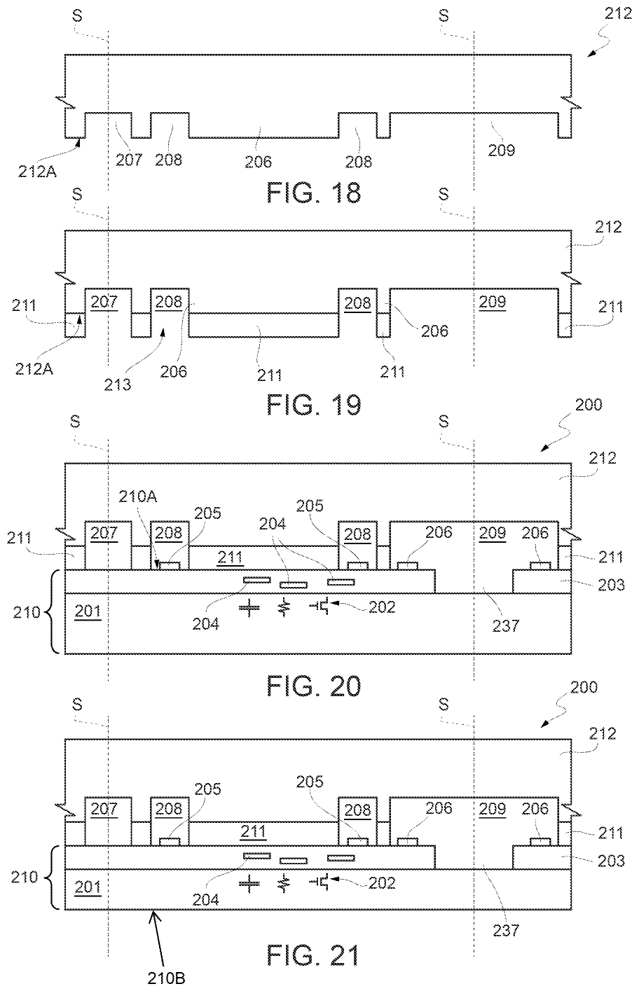

FIGS. 18-30 show steps of a manufacturing process according to an alternative embodiment. In these Figures, parts similar to those of FIGS. 1-15 are indicated with reference numbers increased by 100.

In FIG. 18, a carrier wafer 212 of semiconductor material, such as silicon, has already been processed to form a first, a second, and a third recess 207, 208 and 209.

For example, the carrier wafer 212 may be thermally oxidized, so as to form a protection layer (not shown) which coats it completely, also on the side edges; then the protection layer (not shown) is etched on one face thereof using a resist mask (not shown) to form openings where it is desired to form recesses 207, 208, 209; the resist mask is removed; the carrier wafer 212 is etched using the protection layer (not shown) as a hard mask; then the protective layer is removed.

The carrier wafer 212 has a main face 212A having at least the first recess 207 (intended to be arranged at a scribe line S), the second recesses 208 (intended to allow the electrical connection of the bumps which are still to be formed), and the third recess 209 (intended to be arranged at a scribe line S and to allow the connection between the ASIC wafer to be bonded and the MEMS wafer, as explained below).

The recesses 207, 208, 209 are separated by protruding portions 206 of the carrier wafer 212.

In FIG. 19, a carrier wafer bonding layer 211, patterned, is printed on the protruding portions 206. For example, the carrier wafer bonding layer 211 is of glass frit or metal. However, other application techniques are possible.

The carrier wafer bonding layer 211 forms openings 213, aligned with the recesses 207, 208, 209, as explained below.

In FIG. 20, an ASIC wafer 210 is bonded to the carrier wafer 212, front-to-front, using the carrier wafer bonding layer 211.

Similar to the embodiment of FIGS. 1-15, the ASIC wafer 210 has already been processed so as to form, in a body 201 of semiconductor material such as silicon, electronic components 202; form a passivation layer 203 embedding metallizations 204; and form first contact pads 205 on the passivation layer 203.

In FIG. 20, the passivation layer 203 has also already been selectively removed (for example, through an etching and lithographic process) so as to form a contact opening 237 which, after bonding the ASIC wafer 210 and the carrier wafer 212, is aligned with the third recess 209, although as shown in FIG. 20, it is narrower.

Furthermore, the main face 212A of the carrier wafer 212 is bonded to the front surface 210A of the ASIC wafer 210 so that the recesses 207, 208, 209 are arranged at the first contact pads 205.

A composite wafer 200 is thus formed, where the openings 213 in the carrier wafer bonding layer 211 are superimposed on the first contact pads 205.

In FIG. 21, the body 201 is thinned and polished from the back, so as to reach a reduced thickness, for example, 120 μm. A rear surface 210B of the ASIC wafer 210 is thus formed.

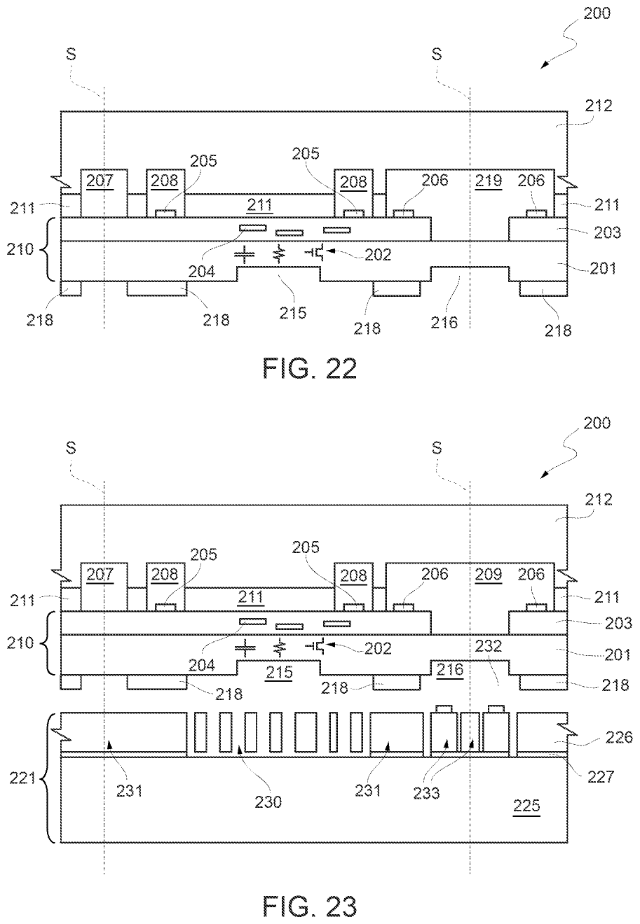

In FIG. 22, a first cavity 215 and a second cavity 216 are formed into the body 201, from the rear surface 210B. Also here a photolithographic process and a masked etching of the silicon may be used.

Furthermore, in FIG. 22, bonding regions 218 are formed on the rear surface 210B of the ASIC wafer 210. For example, the bonding regions 218 may be of glass frit, selectively printed on the sides of the cavities 215, 216.

In FIG. 23, the ASIC wafer 210 is bonded to a MEMS wafer 221 through the bonding regions 218, for example, at 270° C. Alternatively, bonding regions of adhesive material may be formed both on the ASIC wafer 210 and on the MEMS wafer 221. The composite wafer 200 is thus obtained.

Also shown in the embodiment, the MEMS wafer 221 comprises a first and a second semiconductor layer 225,226, for example, both of silicon, mutually superimposed and mutually fixed by dielectric regions 227.

Additionally, the MEMS wafer 221 has already been processed so as to form, in the second semiconductor layer 226, MEMS sensitive regions, indicated generically by 230 and supported by suspension structures, which are not shown for clarity.

The second semiconductor layer 226 also forms anchoring regions 231 and fixed portions 233.

Similar to the embodiment of FIGS. 1-15, third contact pads 232 extend on some fixed portions 233 of the MEMS wafer 221.

Also, the geometry is designed so that bonding of the ASIC wafer 201 to the MEMS wafer 221 is performed so that the first cavity 215 faces the suspended structures 230 and the second cavity 216 faces the third contact pads 232.

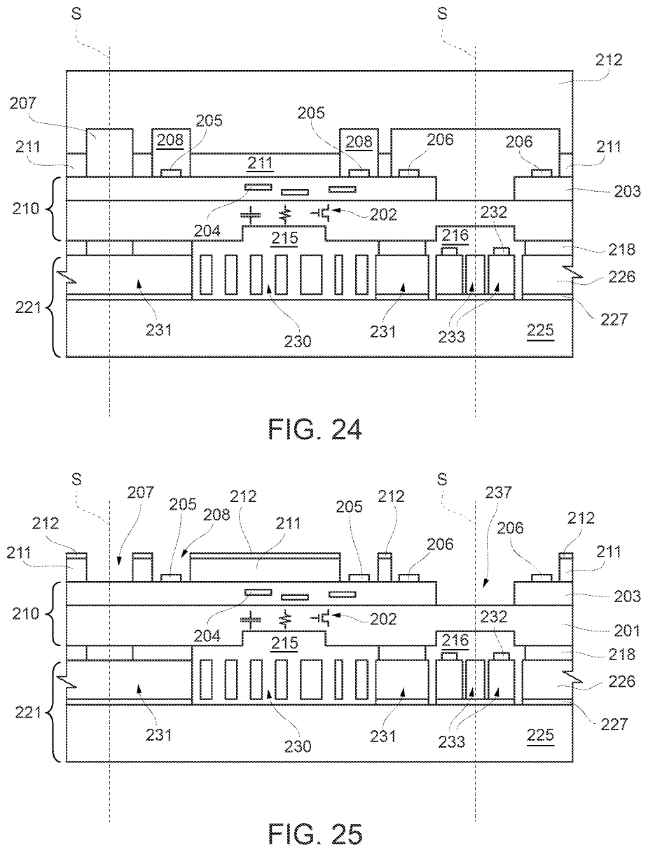

After the bonding (FIG. 24), the composite wafer 200 is thinned from the back, so as to reduce the thickness of the first semiconductor layer 225 of the MEMS wafer 212 down to a reduced value, for example, 100-120 μm.

In FIG. 25, the carrier wafer 212 is thinned to reach at least the bottom of the recesses 207, 208,209, which therefore form through openings (again indicated for sake of simplicity by 207-209), which allow access to the contact pads 205.

For example, after the thinning, the carrier wafer 212 may have a thickness of 10-50 μm.

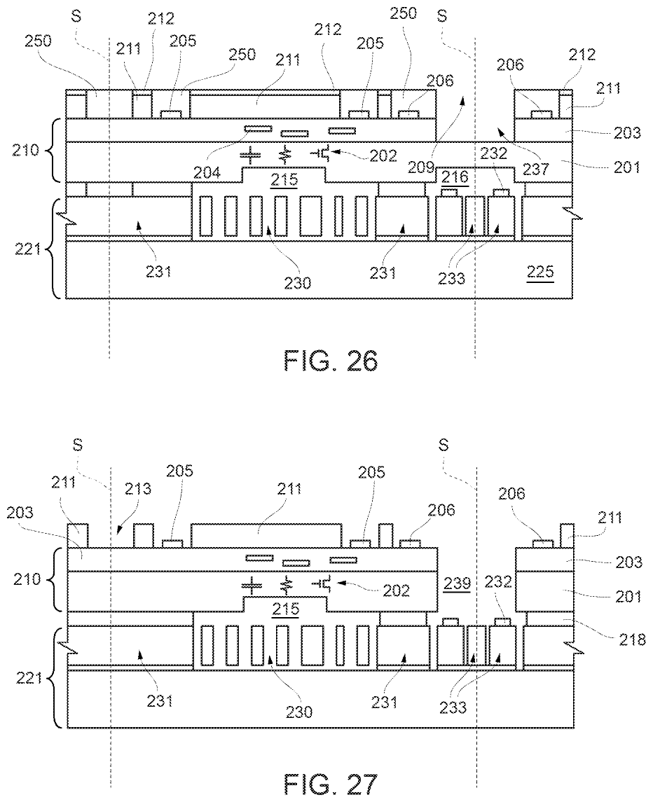

Then, as shown in FIG. 26, masking regions 250 are formed in the recesses 207, 208, 209. To this end, a masking layer, for example of resin, may be deposited above the carrier wafer 212, using a suitable technique, for example, by spinning. The masking layer is selectively removed. It is removed on the contact opening 237, leaving the masking regions 250 in the first recess 207 and in the second recesses 208 and only partially in the third recess 209. The body 201 is therefore here exposed through the contact opening 237.

In FIG. 27, the body 201 is selectively etched and removed throughout its thickness, where exposed, here below the third recess 209 and the contact opening 237. A through opening 239 is thus formed which incorporates part of the third recess 209 and the contact opening 237 and makes the third contact pads 232 accessible from the outside.

Etching of the body 201 also leads to removing the remaining portion of the carrier wafer 212.

After removing the masking regions 250, the structure of FIG. 27 is obtained.

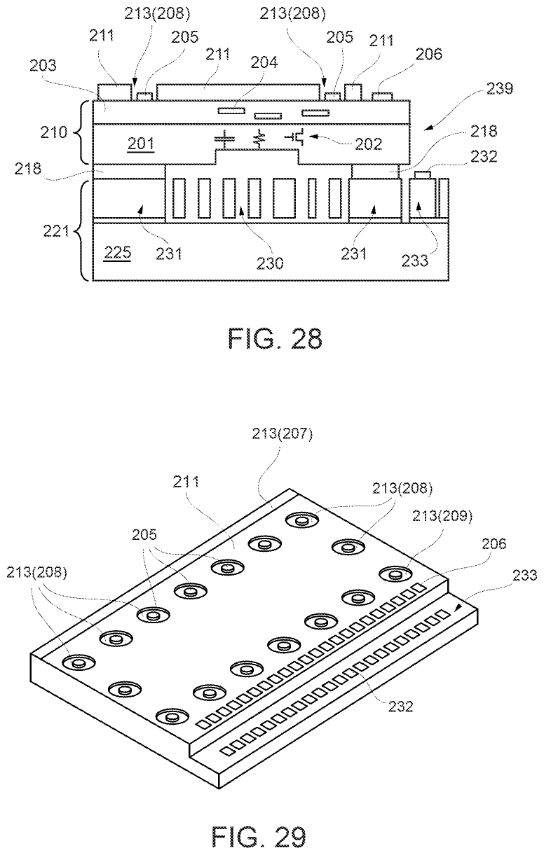

In FIG. 28, the composite wafer 200 is singulated along the scribe central lines S. Also here, dicing may occur using a dicing saw or by laser dicing, in a per se known manner, and leads to obtaining a composite die 240.

FIG. 29 shows in top perspective view the composite die 240 thus obtained. In this Figure, the openings 213 in the carrier wafer bonding layer 211 are clearly visible.

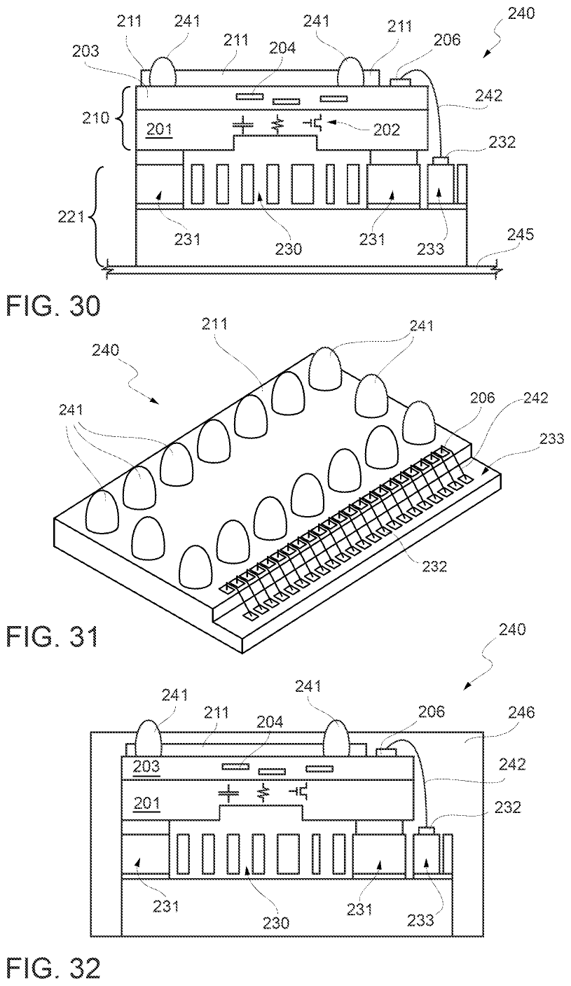

In FIG. 30, the composite die 240 is fixed to a tape 245, generally adhesive, having other composite dice 240 fixed thereto (in a manner not shown), at a mutual distance. Then, bumps 241 are formed on the first contact pads 205. For example, the bumps 141 may be formed as explained above for the bumps 141 of FIG. 12. Furthermore, bonding wires 242 are formed which electrically couple the second contact pads 206 to the third contact pads 232 (“wirebonding”). As an alternative to what has been shown, the bumps 241 and/or the bonding wires 242 may be formed before dicing the composite wafer 200, at wafer level, after the step of FIG. 27.

FIG. 31 shows in top perspective view the composite die 240 thus obtained. In this Figure, the carrier wafer bonding layer 211, bumps 241, and the wires 242 are clearly visible.

In FIG. 32, the composite die 240 is packaged by a sealing mass 246, for example, of resin. The structure thus obtained is subsequently singulated, obtaining packaged devices 240, each forming a MEMS system. Also, the packaged device 240 thus obtained has a very reduced height, up to 360 μm, thanks to the complete removal of the carrier wafer, the reduced height of the carrier wafer bonding layer 211 (which remains completely embedded in the sealing mass 246), and to the formation of external connections through bumps. The packaged device 240 may also be manufactured using manufacturing steps common in this type of devices and not complex, at comparatively low costs. The device has a wide layout flexibility, with contact pads that may be arranged on different sides and without constraints as regards to the positioning of the bumps.

It is clear that modifications and variations may be made to the device and the manufacturing process described and illustrated herein without thereby departing from the scope of the present disclosure, as defined in the attached claims. For example, the different embodiments described may be combined so as to provide further solutions.

Furthermore, if allowed by the nature of the MEMS structures in the MEMS wafer 121, 221 and the thickness of the carrier wafer bonding layer 111, 211, the MEMS device may not have the cavities 115, 116; 215, 216.

Although more complicated, in the solution of FIGS. 17-32, the carrier wafer bonding layer 211 might be formed on the ASIC wafer 210.

Example 1: a process for manufacturing a microelectromechanical device comprises:
bonding a first wafer (110; 210) of semiconductor to a second wafer (112; 212), the first wafer integrating electronic components (102; 202);
thinning the first wafer (110; 210);
bonding the first wafer (110; 210) to a third wafer (121; 221), the third wafer including patterned structures (130);
thinning the third wafer (121; 221);
removing the second wafer (112; 212) to obtain a composite wafer (100; 100′; 200) having a main surface (110A) formed by the first wafer;
electrically coupling the first wafer (110; 210) and the third wafer (121; 221) through internal electrical coupling structures (142; 242);
forming external connection regions (141; 241) on the main surface (110A); and
forming a package (146; 146′; 246) packaging the first wafer (110; 210), the third wafer (121; 221) and the internal electrical coupling structures (142; 242) and partially surrounding the external connection regions (141; 241), the external connection regions protruding partially from the package.

Example 2: in the process according to the preceding example, the first wafer (110; 210) may be an ASIC wafer and the third wafer (121; 221) may be a MEMS wafer.

Example 3: in the process according to example 1 or 2, the second wafer (112; 212) may be of semiconductor or glass.

Example 4: in the process according to example 1 or 2, the second wafer 112 may be of glass and removing the second wafer comprises detaching the second wafer through laser light application.

Example 5: the process according to any of examples 1-3 may further comprise, before bonding the first wafer (210) to the second wafer (212), forming first and second recesses (207, 208) in the second wafer and forming contact regions (205) on the main surface (110A) of the first wafer, wherein:
bonding the first wafer (210) to the second wafer (212) comprises forming a bonding layer (218) having first bonding layer openings (213) at the first and second recesses (207, 208) and arranging the first and second recesses (207, 208) of the second wafer and the first bonding layer openings (213) at the contact regions (205) of the first wafer;
removing the second wafer (212) comprises thinning the second wafer up to reaching the first and second recesses (207, 208), forming through recesses (207, 208); and
forming external connection regions comprises forming bumps (241) in the first bonding layer openings (213).

Example 6. The process according to the preceding example may further comprise, before bonding the first wafer (210) to the second wafer (212), forming third recesses (209) in the second wafer; wherein bonding the first wafer (210) to the second wafer (212) may further comprise forming second bonding layer openings (213) at the third recesses (209); after the step of removing the second wafer (212), removing a portion of the body (201) below the third recesses (209), forming through openings (239) in the body (210); and electrically coupling the first wafer (210) and the third wafer (221) may comprise forming coupling wires (242) extending between contact regions (206) on the main surface (210A) of the first wafer (210) and contact regions (232) extending on the third wafer (221) below the through openings (239).

Example 7. In the process according to any of the preceding examples, the external connection regions may be bumps and form an LGA—Land Grid Array—interface.

Example 8. In the process according to any of examples 1-6, the internal electrical coupling structures may be bonding wires (142; 242) extending between external contact pads (106; 206) formed on the main surface (110A; 210A) of the first wafer (110; 210) and further contact pads (132; 232) formed on the third wafer (121; 221).

Example 9. The process according to any of the preceding examples may further comprise forming cavities (115; 116) in the first wafer before bonding the first wafer to the third wafer.

Example 10. In the process according to any of examples 1-5, the third wafer (121; 221) may comprise third contact pads (132; 232) facing the first wafer (110; 210), the process may further comprise, after the step of removing the second wafer (112; 212), selectively removing a portion of the body (101; 201) above the third contact pads (132; 232), wherein electrically coupling the first wafer (110; 210) and the third wafer (121; 221) may comprise forming coupling wires passing through the removed portion of the body (101; 201).

Example 11. The process according to any of the preceding examples, comprising singulating the composite wafer (110; 200) before or after the steps of electrically coupling the first and the third wafers (110; 210, 121; 221), forming external connection regions (141; 241) and forming a package (146; 146′; 246).

Example 12. A device may comprise:
a first die (110; 210) of semiconductor integrating electronic components (102; 202);
a second die (121; 221) of semiconductor bonded to the first die and forming patterned structures (130; 230), the first die having a main surface (110A; 210A);
internal electrical coupling structures (142; 242) electrically coupling the main surface (110A; 210A) of the first die (110; 210) to the second die (121; 221);
external connection regions (141; 241) on the main surface of the first die (110; 210); and
a package (146; 146′; 246) packaging the first die (110; 210), the second die (121; 221) and the internal electrical coupling structures (142; 242) and partially surrounding the external connection regions (141; 241), the external connection regions protruding partially from the package.

Example 13. In the device according to the preceding example, the package (146; 146′; 246) may cover and be in contact with the main surface (110A; 210A) of the first die (210).

Example 14. The device according to example 12 may comprise a bonding layer (211) superimposed on the main surface (210A) of the first die (210), wherein the package (146; 146′; 246) may cover and be in contact with the bonding layer (211).

Example 15. In the device according to the preceding example, the bonding layer (211) may have through openings (213) and the external connection regions (241) may traverse the through openings (213).

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for manufacturing a microelectromechanical device, comprising:
bonding a first wafer of semiconductor to a second wafer, the first wafer integrating electronic components;
thinning the first wafer;
bonding the first wafer to a third wafer, the third wafer including patterned structures;
thinning the third wafer;
removing the second wafer to obtain a composite wafer having a main surface formed by the first wafer;
electrically coupling the first wafer and the third wafer through internal electrical coupling structures;
forming external connection regions on the main surface; and
forming a package packaging the first wafer, the third wafer and the internal electrical coupling structures and partially surrounding the external connection regions, the external connection regions protruding partially from the package.

2. The method according to claim 1, wherein the first wafer is an Application Specific Integrated Circuit wafer and the third wafer is a Micro-Electro-Mechanical-System wafer.

3. The method according to claim 1, wherein the second wafer is of semiconductor material or glass.

4. The method according to claim 1, wherein the second wafer is of glass and removing the second wafer comprises detaching the second wafer through laser light application.

5. The method according claim 1, further comprising, before bonding the first wafer to the second wafer, forming first and second recesses in the second wafer and forming contact regions on the main surface of the first wafer, wherein:
bonding the first wafer to the second wafer comprises forming a bonding layer having first bonding layer openings at the first and second recesses and arranging the first and second recesses of the second wafer and the first bonding layer openings at the contact regions of the first wafer;
removing the second wafer comprises thinning the second wafer up to reaching the first and second recesses, forming through recesses; and
forming external connection regions comprises forming bumps in the first bonding layer openings.

6. The method according to claim 1, further comprising, before bonding the first wafer to the second wafer, forming third recesses in the second wafer, wherein:
bonding the first wafer to the second wafer further comprises forming second bonding layer openings at the third recesses;
after the step of removing the second wafer, removing a portion of a body below the third recesses, forming through openings in the body; and
electrically coupling the first wafer and the third wafer comprises forming coupling wires extending between contact regions on the main surface of the first wafer and contact regions extending on the third wafer below the through openings.

7. The method according to claim 1, wherein the external connection regions are bumps and form an Land Grid Array interface.

8. The method according to claim 1, wherein the internal electrical coupling structures are bonding wires extending between external contact pads formed on the main surface of the first wafer and further contact pads formed on the third wafer.

9. The method according to claim 1, further comprising forming cavities in the first wafer before bonding the first wafer to the third wafer.

10. The method according to claim 1, wherein the third wafer comprises third contact pads facing the first wafer, the process further comprising, after the step of removing the second wafer, selectively removing a portion of the body above the third contact pads, wherein electrically coupling the first wafer and the third wafer comprises forming coupling wires passing through the removed portion of the body.

11. The method according to claim 1, further comprising singulating the composite wafer before or after the steps of electrically coupling the first and the third wafers, forming external connection regions and forming a package.

12. A device, comprising:
a first die of semiconductor integrating electronic components;
a second die of semiconductor bonded to the first die and forming patterned structures, the first die having a main surface;
internal electrical coupling structures electrically coupling the main surface of the first die to the second die;
external connection regions on the main surface of the first die; and
a package packaging the first die, the second die and the internal electrical coupling structures and partially surrounding the external connection regions, the external connection regions protruding partially from the package.

13. The device according to claim 12, wherein the package covers and is in contact with the main surface of the first die.

14. The device according to claim 12, further comprising a bonding layer superimposed on the main surface of the first die, wherein the package covers and is in contact with the bonding layer.

15. The device according to claim 14, wherein the bonding layer has through openings and the external connection regions traverse the through openings.

16. A MEMS device, comprising:
a first die that includes:
a main surface;
a body and a passivation layer on the body;
a second die having a first semiconductor layer and an anchoring region on the first semiconductor layer, the second die bonded to the first die by a bonding region and forming patterned structures;
a first contact pad and a second contact pad on the passivation layer;
a fixed portion on the first semiconductor layer opposite to the anchoring region; and
a third contact pad on the fixed portion.

17. The MEMS device of claim 16, further comprising a first recess, a second recess, and a third recess.

18. The MEMS device of claim 17, further comprising a through opening that incorporates a part of the third recess.

19. The MEMS device of claim 16, wherein the passivation layer includes embedded metallizations.

20. The MEMS device of claim 16 further comprising external connection regions on the first contact pads, the external connection regions protruding partially from the device.
